(19) United States
(12) Patent Application Publication
(10) Pub. No.: US 2007/0138643 A1
(43) Pub. Date: Jun. 21, 2007

(54) Semiconductor device having metal interconnection structure and method for forming the same

(75) Inventor: Sung Joong Joo, Incheon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU ELECTRONICS CO., LTD.

(21) Appl. No.: 11/639,299

(22) Filed: Dec. 15, 2006

(30) Foreign Application Priority Data
Dec. 16, 2005 (KR) 10-2005-0124417

(51) Int. Cl. H01L 23/52

(52) U.S. Cl. 257/767

(57) ABSTRACT

A method for forming a metal interconnection structure in a semiconductor device is provided. In one embodiment, first and second diffusion barrier layers are sequentially formed, and then an aluminum pad is formed on the diffusion barrier layers. The first diffusion barrier layer may be made of titanium-silicon-nitride. In addition, the second diffusion barrier layer may be made of titanium, titanium-nitride, or titanium/titanium-nitride.

### RELATED APPLICATION

This application is based upon and claims the benefit of priority to Korean Application No. 10-2005-0124417, filed on Dec. 16, 2005, the entire contents of which are incorporated herein by reference.

### BACKGROUND

1. Technical Field

The present invention relates to a semiconductor technology. More specifically, the present invention relates to a metal interconnection structure of a semiconductor device, and a method for forming the same, capable of improving an electron migration phenomenon.

2. Related Art

As semiconductor devices are fabricated to have a very small size, the resistance of a metal interconnection structure and the parasitic capacitance of an inter-layer dielectric layer may cause a resistance-capacitance (RC) delay to increase. In order to prevent the RC delay from increasing, the metal interconnection structure may be made of copper (Cu), which has a low specific resistance.

However, a semiconductor chip may include electrode pad made of aluminum (Al). The electrode pad leads the semiconductor chip to the exterior by electrically connecting the semiconductor chip to, for example, a lead frame, or a printed circuit board, thereby allowing a probe to test the electrical characteristics of the semiconductor chip. Accordingly, in order to avoid problems caused by the diffusion of copper when the electrode pad contacts the probe, the electrode pad may include aluminum (Al). Since the electrode pad is formed at an upper layer of the semiconductor chip, and a copper metal interconnection structure is formed at a lower layer of the semiconductor chip, an interfacial surface exists between the electrode pad and the copper metal interconnection structure. Accordingly, problems caused by the diffusion of copper still remain.

The copper diffusion may bring about electron migration, which may change the structure of a circuit. In other words, if copper diffuses due to the copper diffusion phenomenon, a metal structure may change, causing changes to the circuit structure.

In addition, since aluminum (Al) used for the electrode pad has an inferior adhesive property, aluminum (Al) may be tom at the interfacial surface that contacts copper.

In order to prevent this phenomenon, a titanium-silicon-nitride (TiSiN) layer 4 is formed between an electrode pad 8 made of aluminum and a metal interconnection structure 2 made of copper, as shown in FIG. 1. The titanium-silicon-nitride (TiSiN) layer 4 may shield the diffusion of copper, and improve the adhesive property between copper and aluminum.

However, although the titanium-silicon-nitride (TiSiN) layer 4 may shield the diffusion of copper when a contact area between aluminum and copper is small, if the contact area between the aluminum and the copper is large, the copper diffusion may still occur at the border of the contact area due to a stress difference between the aluminum and the copper.

### SUMMARY

The present invention has been made to solve the above problem occurring in the prior art, and to prevent copper from diffusing at a contact area between a copper interconnection and an aluminum pad.

Accordingly, there is provided to a method for forming a metal interconnection, in which first and second diffusion barrier layers are sequentially formed, and then an aluminum pad is formed. At this time, it is preferred that the first diffusion barrier layer includes titanium-silicon-nitride. In addition, it is preferred that the second diffusion barrier layer includes one selected from the group consisting of titanium, titanium-nitride, and titanium/titanium-nitride.

### BRIEF DESCRIPTION OF DRAWINGS

FIG. 1 is a sectional view showing a conventional metal interconnection structure; and

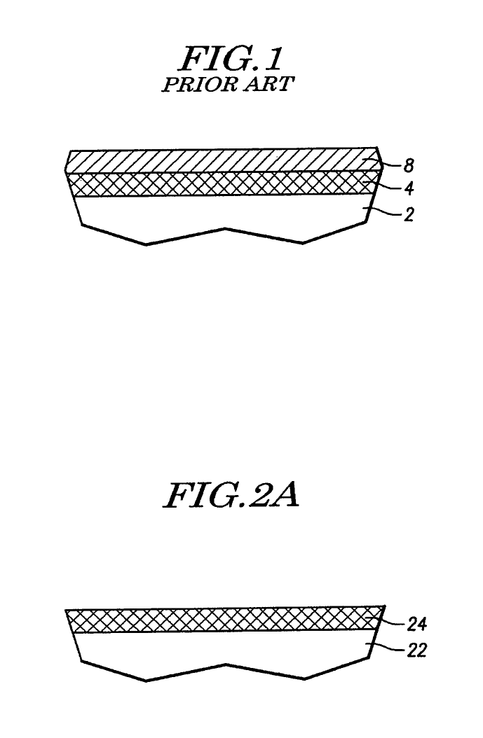

FIGS. 2A to 2C are sectional views showing a method for forming a metal interconnection structure, consistent with the present invention.

### DETAILED DESCRIPTION

Hereinafter, an embodiment consistent with the present invention will be described with reference to accompanying drawings.

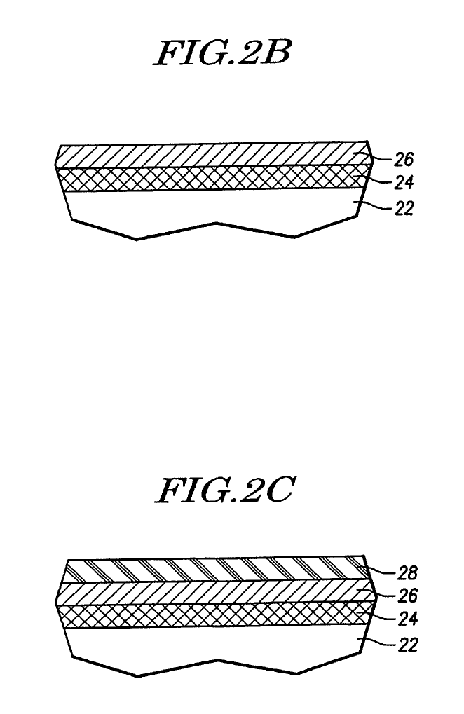

FIGS. 2A to 2C are sectional views showing a method for forming a metal interconnection structure, consistent with the present invention.

A first diffusion barrier layer 24 is formed on a copper interconnection structure 22, as shown in FIG. 2A. First diffusion barrier layer 24 may be made of titanium-silicon-nitride (TiSiN). In this case, the titanium-silicon-nitride (TiSiN) may be formed by various well-known schemes. Thus, it is possible to prevent the diffusion of copper used for a lower interconnection structure in a semiconductor device by means of first diffusion barrier layer 24.

Subsequently, as shown in FIG. 2B, a second diffusion barrier layer 26 is formed on first diffusion barrier layer 24. Second diffusion barrier layer 26 may be made of titanium (Ti) or titanium-nitride (TiN). In addition, second diffusion barrier layer 26 may be made of titanium/titanium-nitride(Ti/TiN).

In one embodiment, second diffusion barrier layer 26 is made of titanium (Ti), and has a thickness in the range of about 100 Å to 500 Å. In another embodiment, second diffusion barrier layer 26 is made of titanium-nitride(TiN), and has a thickness in the range of about 100 Å to 600 Å. In still another embodiment, second diffusion barrier layer 26 is formed of a bilayer, which is made of titanium/titanium-nitride(Ti/TiN), where titanium has a thickness in the range of about 50 Å to 150 Å, and titanium-nitride(TiN) has a thickness in the range of about 100 Å to 300 Å. Such thicknesses of second diffusion barrier layer 26 are suitable for the characteristics of a barrier, and may be changed according to the characteristics of the semiconductor device.

After forming second diffusion barrier layer 26, an upper metal pad 28 is formed on second diffusion barrier layer 26 by coating aluminum (Al), as shown in FIG. 2C. However, it is appreciated that upper metal pad 28 may be formed by coating other metals.

In other words, according to an embodiment consistent with the present invention, first and second diffusion barrier layers 24 and 26 are formed between lower metal interconnection structure 22 and upper metal pad 28. Such first and second diffusion barrier layers 24 and 26 serve as barriers with respect to metal interconnection structure 22 and electrode pad 28, respectively. Diffusion barrier layer 24 made of Titanium-Silicon-Nitride (TiSiN) has a superior adhesive property relative to copper, which may prevent the diffusion of the copper. In contrast, second diffusion barrier layer 26 has a superior adhesive property relative to aluminum.

Since first diffusion barrier layer 24, made of titanium-silicon-nitride (TiSiN), is obtained by adding silicon (Si) to titanium-nitride (TiN) through a chemical vapour deposition (CVD) scheme, and first diffusion barrier layer 24 has a property similar to that of second diffusion barrier layer 26, first diffusion barrier layer 24 has a superior adhesive property relative to second diffusion barrier layer 26.

In other words, diffusion barrier layers 24 and 26 have superior adhesive properties relative to metal interconnection structure 22 and electrode pad 28, respectively. In addition, diffusion barrier layers 24 and 26 have a superior adhesive property therebetween. Accordingly, even if the contact area is large, it is possible to prevent a copper diffusion phenomenon from occurring at the border of the copper interconnection.

While the invention has been shown and described with reference to certain embodiments thereof, it will be understood by those skilled in the art that various modifications and alterations may be made without departing from the spirit and scope of the invention as defined in the appended claims.

What is claimed is:

1. A semiconductor device having a metal interconnection structure, comprising:
a lower copper interconnection structure formed on a silicon substrate;
a titanium-silicon-nitride layer formed on the lower copper interconnection structure;
a diffusion barrier layer formed on the titanium-silicon-nitride layer; and
an aluminum metal pad formed on the diffusion barrier layer;
wherein the diffusion barrier layer is formed of a material having an adhesive property superior to that of the titanium-silicon-nitride layer and the aluminum metal pad.

2. The semiconductor deviceof claim 1, wherein the diffusion barrier layer comprises a material selected from the group consisting titanium, titanium-nitride, and titanium/titanium-nitride.

3. The semiconductor deviceof claim 2, wherein the diffusion barrier layer is formed of titanium having a thickness of about 100 Å to 500 Å.

4. The semiconductor deviceof claim 2, wherein the diffusion barrier layer is formed of titanium-nitride having a thickness of about 100 Å to 600 Å.

5. The semiconductor deviceof claim 2, wherein the diffusion barrier layer is formed of a bilayer comprising a titanium layer having a thickness of about 50 Å to 150 Å, and a titanium-nitride layer having a thickness of about 100 Å to 300 Å.

6. A method for forming a metal interconnection structure in a semiconductor device, the method comprising:
forming a first diffusion barrier layer on a copper interconnection structure formed on a semiconductor substrate, wherein the first diffusion barrier layer has an adhesive property superior to that of the copper interconnection structure;
forming a second diffusion barrier layer on the first diffusion barrier layer, wherein the second diffusion barrier layer has a adhesive property superior to the first diffusion barrier layer; and
forming an aluminum pad on the second diffusion barrier layer.

7. The method of claim 6, wherein the first diffusion barrier layer is formed of titanium-silicon-nitride.

8. The method of in claim 7, wherein the second diffusion barrier layer comprises a material selected from the group consisting titanium, titanium-nitride, and titanium/titanium-nitride.

9. The method of claim 8, wherein the second diffusion barrier layer is formed of titanium having a thickness of about 100 Å to 500 Å.

10. The method of 8, wherein the second diffusion barrier layer is formed of titanium-nitride having a thickness of about 100 Å to 600 Å.

11. The method of claim 8, wherein the second diffusion barrier layer is formed of a bilayer including a titanium layer having a thickness of about 50 Å to 150 Å and a titanium-nitride layer having a thickness of about 100 Å to 300 Å.
